(19) United States
(12) Patent Application Publication
(10) Pub. No.: US 2026/0274758 A1
(43) Pub. Date: Sep. 17, 2026

(54) FORMING CERAMIC COMPONENTS BY RAPID DENSIFICATION OF POROUS PREFORMS

(71) Applicant: Textron Systems Corporation, Hunt Valley, MD (US)

(72) Inventors: Zachary Michael Tobin, Cambridge, MA (US); Michael Robert Favaloro, Amesbury, MA (US)

(21) Appl. No.: 19/565,168

(22) Filed: Mar. 12, 2026

Related U.S. Application Data
(60) Provisional application No. 63/771,175, filed on Mar. 13, 2025.

(51) Int. Cl. C04B 38/06

(52) U.S. Cl. CPC C04B 38/0615

(57) ABSTRACT

Techniques are directed to manufacturing a ceramic component. The techniques include placing a porous preform into a preceramic liquid precursor such that the preceramic liquid precursor permeates into the porous preform. The techniques further includes heating the porous preform to a cracking temperature of the preceramic liquid precursor to deposit ceramic material onto and within the porous preform.

### CROSS-REFERENCE TO RELATED APPLICATIONS

This application claims the benefit of U.S. Provisional Patent Application No. 63/771,175, filed Mar. 13, 2025, the contents and teachings of which are incorporated herein by reference in their entirety.

### BACKGROUND

Some ceramic materials exhibit properties that make them suitable for extreme environments. For example, some ceramic materials have high strength, low density, and resistance against high temperatures and other demanding operating conditions.

Some ceramic materials are produced through a process known as chemical vapor deposition (CVD). In CVD, a substrate is exposed to a vaporous precursor which reacts with and decomposes onto the substrate as a ceramic. The substrate and the ceramic may form a composite, with the vaporous precursor infiltrating the substrate and decomposing into ceramic within the substrate.

### SUMMARY

Certain embodiments are directed to a method of manufacturing a ceramic component. The method includes placing a porous preform into a preceramic liquid precursor such that the preceramic liquid precursor permeates into the porous preform. The method further includes heating the porous preform to a cracking temperature of the preceramic liquid precursor to deposit the decomposed ceramic material onto and within the porous preform.

Other embodiments are directed to a ceramic component that includes a high-entropy ceramic (HEC) material having submicron pores. The submicron pores inhibiting crack propagation within the ceramic component.

The foregoing summary is presented for illustrative purposes to assist the reader in readily grasping example features presented herein; however, this summary is not intended to set forth required elements or to limit embodiments hereof in any way. One should appreciate that the above-described features can be combined in any manner that makes technological sense, and that all such combinations are intended to be disclosed herein, regardless of whether such combinations are identified explicitly or not.

### BRIEF DESCRIPTION OF THE SEVERAL VIEWS OF THE DRAWINGS

The foregoing and other features and advantages will be apparent from the following description of particular embodiments, as illustrated in the accompanying drawings, in which like reference characters refer to the same or similar parts throughout the different views. The drawings are not necessarily to scale, emphasis instead being placed upon illustrating the principles of various embodiments.

FIG. 1 is a block diagram of an example environment in which certain embodiments of rapid densification techniques can be practiced.

FIG. 2 is a line chart showing a temperature gradient of components in the example environment of FIG. 1 in accordance with certain embodiments.

FIG. 3 is a flowchart showing an example procedure for manufacturing a ceramic component in accordance with certain embodiments.

FIG. 4 is a line chart showing density as a function of processing time for the disclosed rapid-densification techniques versus known techniques in accordance with certain embodiments.

FIGS. 5a through 5c are block diagrams showing heating arrangements suitable for the disclosed rapid densification techniques in accordance with certain embodiments.

FIG. 6 is a block diagram showing placement of a heating system in a preform in accordance with certain embodiments.

FIG. 7 is a flowchart of a procedure for manufacturing components through rapid densification in accordance with certain embodiments.

### DETAILED DESCRIPTION

Unfortunately, the above-described production of ceramic components using CVD is relatively slow. Along these lines, the vaporous precursor tends to decompose into ceramic starting from an outer surface of the substrate, forming a layer of ceramic that inhibits later infiltration of the precursor further into the substrate. The lack of infiltration may be somewhat mitigated through certain machining steps that allow additional infiltration after forming an initial layer of ceramic. These machining steps can open up a sealed surface to further infiltrate the substrate. However, even with these additional machining steps, CVD cannot reach a fully idealized density and may have extremely long manufacturing times (e.g., 300-1000 hours per component). What is needed, therefore, is a way of more quickly producing ceramic components.

The above need is addressed, at least in part, by an improved technique directed to production of a toughened ceramic component through rapid densification of a porous preform. The technique includes placing the preform into a preceramic liquid precursor and heating the preform to a cracking temperature of the precursor, which causes the liquid precursor to decompose and further causes ceramic material to deposit onto and within the preform. The bulk of the liquid precursor remains relatively low temperature, thereby remaining in a form that allows it to continuously replace the decomposed material as it fills the cavities of the preform.

Advantageously, the above-described technique provides multiple benefits. For example, rapid densification using the liquid precursor may progress significantly faster than CVD (e.g., 1-2 orders of magnitude faster). Further, as densified ceramic material generally progresses from the center of the preform wall to the outside, additional machining steps to improve infiltration may be avoided, simplifying production of ceramic components and further reducing manufacturing times of such components.

Embodiments of the improved technique will now be described. One should appreciate that such embodiments are provided by way of example to illustrate certain features and principles but are not intended to be limiting.

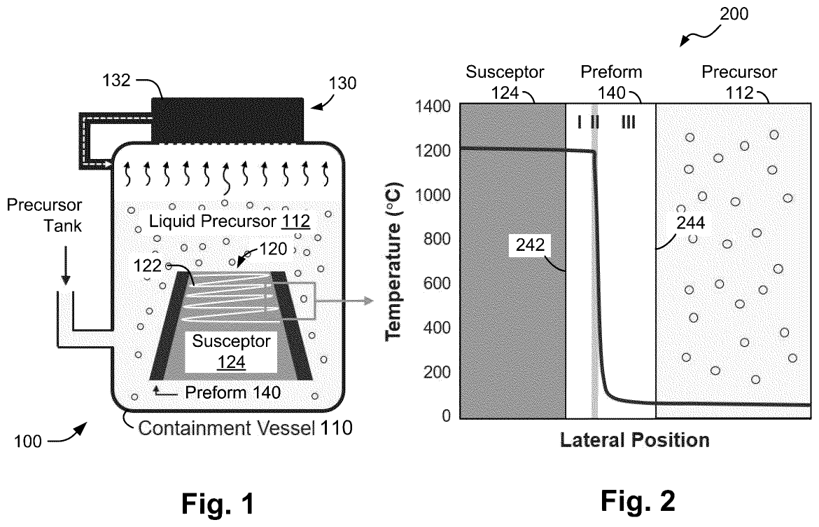

A general discussion of rapid densification, also referred to as film boiling or liquid-vapor phase densification, is provided below with reference to FIGS. 1 and 2, followed by specific examples in which rapid densification is used to create certain components with different material compositions.

FIGS. 1 and 2 illustrate a rapid-densification apparatus and associated process in accordance with certain embodiments. FIG. 1 shows a cross-sectional view of a rapid-densification system 100 that supports densification of a porous preform 140. FIG. 2 shows a line chart 200 that illustrates temperature changes across lateral positions within the rapid-densification system 100 at a given point in time.

As best shown in FIG. 1, the rapid-densification system 100 includes a containment vessel 110 (also referred to herein as simply “vessel 110”). The vessel 110 has an internal chamber that contains liquid precursor 112, which may be supplied continuously or intermittently from a separate precursor tank (not shown). The liquid precursor 112 is constructed and arranged to create dissociated gas species when boiled, which deposit solid material onto a preform. The rapid-densification process supports a variety of liquid precursors that form different solid ceramic materials. The liquid precursor 112 may be selected based on the requirements of the particular application and desired chemistry. In one embodiment, the liquid precursor 112 may be a low-viscosity hydrocarbon liquid to form carbon material. Alternatively, other organic or even inorganic substances may be used, such as polysilazanes or polysiloxanes. For example, the liquid precursor 112 may instead be a preceramic liquid precursor that produces intermediate silazane or siloxane vapors during the rapid-densification process to form ceramic or ceramic carbide material. In some arrangements, the liquid precursor 112 is preferably a dielectric having a dielectric constant of at least above 0.5, more preferably above 1, and most preferably above 1.5.

The vessel 110 is equipped with a heating system 120 constructed and arranged to supply heat to components and/or materials within the internal chamber. Various types of heating arrangements may be used either individually or in combination to support one or more types of heat transfer, e.g., induction heating, resistive heating, and so forth. By way of example only, the heating system 120 as shown in FIG. 1 includes an induction coil 122 and a susceptor 124 that together support induction heating. A power source (not shown) supplies electric current that passes through the induction coil 122. The electric current creates an electromagnetic field that supplies electromagnetic energy to the susceptor 124. The susceptor 124 converts the electromagnetic energy into heat, which emanates from the susceptor 124 in a generally uniform manner. However, as will be discussed in greater detail below, other heating arrangements may be used, such as those that do not use a susceptor.

In some arrangements, such as those that employ induction heating, the vessel 110 is preferably made from nonmagnetic materials such as quartz, glass, aluminum, austenitic stainless steel, ceramic, polymer matrix composites (PMC) or combinations thereof.

Optionally, the rapid-densification system 100 includes other componentry 130 that supports the rapid-densification process, such as a condenser 132 constructed and arranged to condense volatile compounds (e.g., hydrogen, methane, and ethylene) emanating from the vessel 110. The condenser 130 may be used to reliquefy vapors and to maintain desired operating conditions (e.g., thermal equilibrium) during the rapid-densification process. In some arrangements, the condenser 132 contains water-carrying coils in a nitrogen atmosphere that condense the volatile compounds, which drop back into the vessel 110 when condensed. Examples of other componentry 130 include fluid pumps and valves, electrical connectors, sensors, computerized circuitry, and so forth.

During example operation, a porous preform 140 is placed into the liquid precursor 112 in the vessel 110. By way of example only, the preform 140 as shown in FIG. 1 is an open-ended conical tube that extends around the heating system 120. Other shapes and sizes are possible, however. The preform 140 is made of carbon-based strands (e.g., carbon fibers and/or carbon nanotubes), which enables the liquid precursor 112 to permeate into the preform 140 through gaps or spaces between the strands. In some arrangements, placing the preform 140 in the liquid precursor 112 deprives the preform 140 of oxygen.

After the preform 140 is placed into the liquid precursor 112, the heating system 120 supplies heat to the preform 140 to raise the temperature of the preform 140 to a cracking temperature of the liquid precursor 112. The heat causes the liquid precursor 112 within the preform 140 to boil, resulting in the decomposition of the liquid and subsequent deposition of the decomposed solid material onto and within the preform 140. For example, in the case of carbon-based precursors, boiling may result in a pyrolytic deposition of carbon onto the preform 140. Deposition may occur at generally atmospheric pressure.

In some arrangements, heating the preform 140 creates differences in temperature across the preform 140 that impact the deposition of solid material onto the preform 140. For example, as best shown in FIG. 2, an inner surface 242 of the preform 140 contacts the susceptor 124 of the heating system 120, which transmits heat to the preform 140 through the inner surface 242. This arrangement creates a temperature gradient across the preform 140, with higher temperatures closer to the inner surface 242 than an opposing outer surface 244 of the preform 140. This temperature gradient causes the liquid precursor 112 within the preform 140 to begin boiling closer to the inner surface 242 before the outer surface 244, inducing solid material to form closer to the inner surface 242 before the outer surface 244. That is, a densification front forms near the inner surface 242 and progresses toward the outer surface 244. FIG. 2 provides a snapshot of the rapid-densification process at a given instant of time, with distinct regions forming within the preform 140. These regions include a densified portion (I), a densification front (II), and a non-densified portion (III). However, it should be appreciated that other heating arrangements may cause densification to progress in different ways, e.g., densification that begins within the preform itself and extends outwards toward both the inner surface 242 and the outer surface 244.

In some arrangements, the rapid-densification process can be completed in several hours, offering significant cost savings compared to the month(s)-long processing required under other processes, e.g., chemical vapor deposition (CVD), chemical vapor infiltration (CVI), hot isostatic pressure impregnation carbonization (HiPIC), or low-pressure pitch impregnation and carbonization (LoPIC). Further, among the advantages of rapid densification is the ability to produce larger components and to provide control over component shape, with rapid densification having the capability of accommodating components requiring thick walls and/or complex curvatures. In some arrangements, final parts exhibit uniform through-thickness densities and little to no surface porosity.

Another distinct advantage of the rapid-densification process is the ability to use a variety of preform types and structures. Traditional densification approaches are generally limited to phenolic-based prepregs (LoPIC, HiPIC), which may be carbonized and/or graphitized to achieve open porosity and fibrous preforms (CVI). The disclosed rapid-densification process may use either of these routes, offering a potential solution to domestic bottlenecks for qualified preform materials.

Example implementations of the rapid-densification process are described below. As provided in the example implementations, the rapid densification process may be used to create components composed of different materials based on the type of liquid precursor used. Example I illustrates the manufacture of certain high-entropy ceramic (HEC) components. Example II illustrates the manufacture of certain carbon fiber reinforced carbon (carbon/carbon) components.

### EXAMPLE I

### High-Entropy Ceramic Components

Ceramic materials have often been the material of choice when examining structural and high temperature extreme environments. Their combination of properties, including high strength, low density and environmental resistance, make them ideal for a variety of demanding applications as a replacement for metal alloys. One drawback is that monolithic ceramics typically exhibit poor fracture toughness due to the inherent brittle behavior these materials exhibit. One workaround is the use of reinforcement, such as carbon fibers, to fabricate composite materials. These fiber reinforcements add toughening mechanisms via crack deflection and fiber pullout. However, the manufacturability of these materials has remained a challenge, especially with time constraints and required touch labor of some desired applications. It would be desirable to improve fracture toughness of ceramic materials without resorting to such fiber reinforcement.

One avenue being explored to obtain desired properties is by employing a class of materials referred to as “high-entropy ceramics” (HEC). These materials, by employing lattice distortion and other disorder mechanisms, introduce strength and toughening mechanisms into monolithic alloys or ceramics. High-entropy alloys demonstrate mechanical properties similar to or better than commonly used alloys, such as Inconel® 718, and with lower density.

High-entropy ceramic materials have specific characteristics that offer an avenue to providing unique properties. By adding more elements and/or compounds into the system, the total system entropy also increases, as the number of possible positions atoms can take in the lattice has increased. The higher that entropy, the higher the activation energy required for diffusivity, leading to sluggish diffusion and formation of a high-performing oxide protection layer at high temperature. The lattice strain that arises from the higher system entropy gives rise to increased mechanical properties, as the lattice distortions allow for tensile and compressive strains to be relaxed easier. Thus, by increasing the number of inorganic compounds in the ceramic material, the high-entropy effects can be used to an advantage.

As provided herein, improved techniques are directed to producing high-entropy ceramic components through the rapid densification process described above in relation to FIGS. 1 and 2. Such densification uses a mixture of multiple preceramic materials, such as carbides, nitrides, and borides, that together provide a preceramic liquid precursor as the liquid precursor 112. Example preceramic materials include silicon carbide, titanium carbide, hafnium carbide, zirconium carbide, and tantalum carbide. Further examples of preceramic materials include titanium butoxide and zirconium butoxide. By mixing multiple preceramic materials to provide the liquid precursor 112, and cracking the precursor materials, a unique ceramic with mixed phases is created. If enough materials are combined into the final ceramic product, high-entropy ceramic material is produced. The ease of mixing these stable liquid precursors before starting the process allows for multiple possible combinations of the final ceramic part.

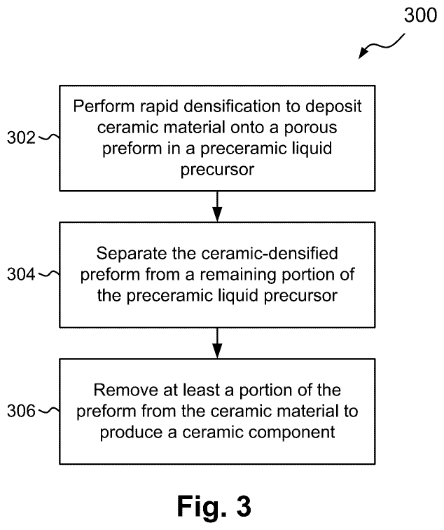

FIG. 3 is a flowchart of a procedure 300 for manufacturing a ceramic component that incorporates the rapid-densification process in accordance with certain embodiments. In the procedure 300, the preform 140 is a sacrificial preform that may be removed after depositing ceramic material using rapid-densification. As described in greater detail below, the resulting ceramic component provides increased toughness, among other advantages.

At 302, a rapid densification process is performed to deposit ceramic material onto the preform 140 in preceramic liquid precursor. For example, the rapid densification process may be performed in accordance with the example operation described above in relation to FIGS. 1 and 2, with the liquid precursor 112 being the preceramic liquid precursor. In some arrangements, the preform 140 is a porous weave or bundle of carbon materials, e.g., carbon fibers and/or carbon nanotubes. However, materials with other properties, structural or compositional, may be employed depending on the requirements for the final component. The rapid-densification process fills in the fabric voids with the ceramic material.

At 304, after ceramic material has been deposited onto the preform 140, the now ceramic-densified preform 140 is separated from a remaining portion of the liquid precursor 112. For example, the ceramic-densified preform 140 may be removed from the vessel 110 and exposed to an environment that contains oxygen (e.g., ambient air).

At 306, after the ceramic-densified preform 140 is separated from the remaining portion of the liquid precursor 112, constituents of the perform 140 are removed from the ceramic material to produce the ceramic component. In some arrangements, the preform constituents are removed by heating the densified preform 140 to a temperature high enough to oxidize the preform constituents, transforming them into a gaseous oxide. For example, carbon-based preforms (e.g., those made of carbon fibers and/or carbon nanotubes) may react with oxygen in the environment to form carbon dioxide. The oxygen may be provided by ambient air or supplied in a controlled manner, e.g., in a specialized oven that supplies pure oxygen. The preform 140 may be oxidized away at suitably low temperature (e.g., about 350° C.) to avoid damage to the ceramic material. Alternatively or in addition, the preform constituents may be removed in other ways, such as washing or lithography.

Advantageously, the resulting ceramic component contains voids that can act as crack deflectors and increase the toughness of the component. That is, by treating the preform 140 as sacrificial instead of structural, voids at a chosen structure and scale may be introduced, which increase surface area and yield crack deflection properties that inhibit crack propagation in the resulting ceramic component, even without additional reinforcement. Further, the removing the preform 140 creates internal surfaces in the ceramic component, which promotes heat transfer from the ceramic component. In some arrangements, heat transfer may include transpirational cooling akin to cooling experienced by certain plants. In such transpirational cooling, water or other fluids traverses through pores in the ceramic component and removes heat from the ceramic component through evaporation and/or convective heat transfer.

The toughened ceramic material may be applicable for use in a broad variety of structures, such as airframes, turbine disks, high-speed vehicles, submarine hulls, etc. Generally, the technique may be used to produce critical structures that experience high operating temperatures and/or chemically harsh operating environments. Other industries where toughened ceramic materials may be used include re-entry vehicles, rocket nozzles, nuclear systems, jet engines, and space flight.

### EXAMPLE II

### Carbon/Carbon Components

Carbon fiber reinforced carbon (also referred to as “carbon/carbon” or “C/C”) is a known composite material. Due to a unique combination of high-temperature properties, carbon/carbon composites have been used as structural materials in high-speed implementations and for reentry vehicles that experience very high-temperature operating conditions. It can be a challenge to produce high-quality C/C in sufficient quantities. This is due in part to bottlenecks for qualified preforms, as well as the expense and time requirements of existing densification processes which lead to undesirably long lead times for C/C materials. The result is a high-demand, low-production-rate material that can cost tens of thousands of dollars per pound for a finalized part such as nosecone or heatshield, with an extremely long lead time.

As provided herein, improved techniques are directed to producing carbon/carbon components through the rapid densification process described above in relation to FIGS. 1 and 2. The rapid densification process may be used to greatly reduce the cost and condense the lead time associated with densifying C/C composites.

In one embodiment, the preform 140 is placed in a low-viscosity hydrocarbon liquid, which acts as the liquid precursor 112. The chain length of the hydrocarbon is carefully chosen to balance the melting and boiling points for operation within a prescribed temperature window. Example hydrocarbons include cyclopentane, cyclohexene, hexene-1, gasoline, toluene, methylcyclohexane, cyclohexane, n-hexane or benzene, or a combination thereof.

Vigorous boiling in the surrounding liquid hydrocarbon (at, e.g., 80° C.) generates carbonaceous vapors that diffuse through the porous preform 140. At elevated temperatures (at or above the cracking temperature of the hydrocarbon) in the densification front, dissociated gas species deposit preferentially on hotter regions of the preform 140 (e.g., near the inner surface 242 of the preform 140 as shown in FIG. 2). As a result, densification begins within the preform 140 and advances along a densification front radially outward (as opposed to radially inward processes of CVI and HiPIC). Initially, little to no decomposition reactions occur near the outer surface 244 of the preform 140, which is cooled by the liquid precursor 112. Advantageously, this arrangement eliminates the need for multiple machining steps to infiltrate the preform 140. The rapid-densification process therefore may use only a single infiltration step lasting several hours.

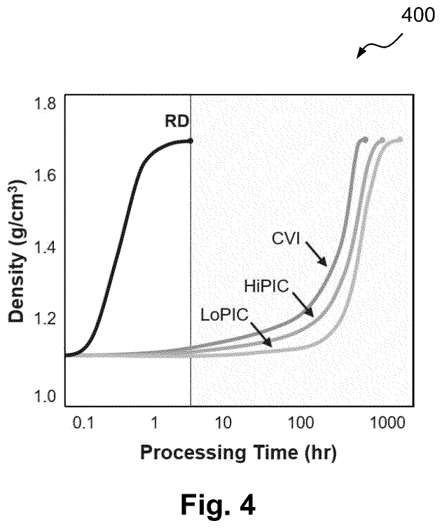

FIG. 4 shows a line chart 400 that illustrates densification rates for an example rapid-densification (RD) process along with the rates for several known C/C densification techniques such as CVI, HiPIC, and LoPIC, with time on a log scale. The rate of densification scales with solid-phase thermal conductivity, operating temperature and frequency, and pressure. Successful infiltration of C/C components can occur at through-thickness rates of ≥1 cm/hr, which is 1-2 orders of magnitude faster than traditional CVI approaches (as shown in FIG. 4). Following a final graphitization step at 2500° C. for 5 hours, final densities of C/C parts made with rapid densification may consistently exceed 90% for a single cycle with average values of 4% porosity readily achievable.

When compared to known approaches to densifying C/C components, the rapid-densification process offers a step forward for the C/C industrial base. Radially inward densification processes such as LoPIC, HiPIC, and CVI require multiple time-consuming infiltration cycles and machining steps. LoPIC and HiPIC are both affected by part shrinkage from thermal expansion and are limited by char yield. For CVI, densification rates are limited by a competition between pyrolysis reactions and the inward diffusion of matrix precursor into the preform. Balancing the two competing processes results in extremely long cycle times (e.g., 300-500 hours for a first cycle) and constant machining of the surface to allow for re-infiltration. By contrast, rapid densification allows for the unhindered diffusion of carbonaceous vapors inward, eliminating the need for in-process machining. Using the disclosed rapid densification technique, multiple densification and machining cycles no longer constitute a rate-limiting step to manufacturing C/C components at scale.

The thermomechanical performance of a C/C component in a high-temperature, ablative operating environment (e.g., high-speed flight) is intricately linked with its processing history and resulting structure. For rapid densification, processing parameters such as operating temperature, frequency, and pressure control the graphitic microstructure, defect concentration, porosity, density gradients, and domain size in C/C components. When compared to traditional approaches such as CVI and HiPIC, C/C components fabricated through rapid densification achieves comparable mechanical, thermal and ablative properties along with equivalent interlayer spacing, implying an ordered graphitic structure.

### Variations in Heating Arrangements

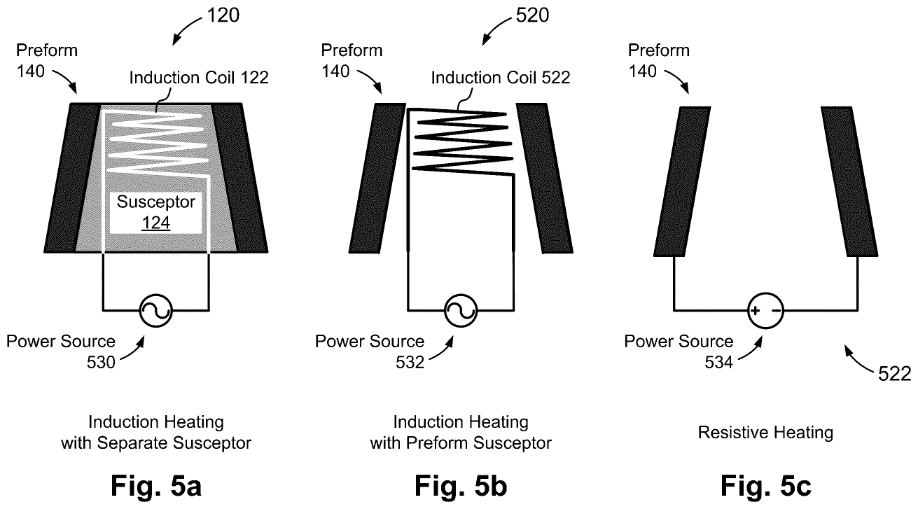

As described above in relation to FIGS. 1 and 2, the rapid-densification system 100 includes the heating system 120, which is constructed and arranged to heat the preform 140 above a cracking temperature of the liquid precursor 112 to deposit solid material onto the preform 140. Additional details regarding the heating system 120 and variations on the heating system 120 will now be described in relation to FIGS. 5a through 5c. The variations may be provided in place of or in addition to the heating system 120 in the rapid-densification system 100.

FIGS. 5a through 5c show respective schematic diagrams of heating arrangements that support the rapid-densification process in accordance with certain embodiments. FIG. 5a shows additional features of the heating system 120 (FIG. 1) that provides induction heating with the induction coil 122 to indirectly heat the preform 140 through the susceptor 124. FIG. 5b shows another heating system 520 that provides induction heating through induction coil 522, with the preform 140 acting as a susceptor. FIG. 5c shows yet another heating system 522 that provides resistive heating to the preform 140.

By way of example only, the preform 140 is provided as a conical tube, with an axis of rotation (not shown) that extends vertically. The figures show a cross-sectional view of the preform 140. Although the preform 140 is shown in two separate parts for simplicity, the parts represent a single contiguous component. However, it should be appreciated that preforms of different shapes or sizes may be provided.

As shown in FIG. 5a, the heating system 120 includes the induction coil 122 and the susceptor 124. The induction coil 122 is coupled to a power source 530, which provides alternating current (AC) that passes through the induction coil 122. The induction coil 122 may be made from copper or other highly conductive material which does not react with the liquid precursor 112 even when the liquid precursor 112 is heated. Electrical current is provided to the induction coil 122 in a generally known manner, e.g., through conductive busses that pass through walls of the vessel 110 using respective seals (e.g., silicone rubber). In some arrangements, because of the large amount of current required, the busses have a sufficient cross section to avoid excess heating. The busses may contain water passages to carry cooling water through the busses and the induction coil 122. The voltage, current, and frequency of operation, as well as the shape of the induction coil 122, are determined by the shape and geometry of the preform 140 as well as preform properties, and generally known techniques may be used to provide induction heating. In one example, operating voltage is in the range from 5 to 750 V, and operating frequency is in the range of 0.1 kHz to 300 MHz.

Generally, the preform 140 is placed in the vessel 110 in close proximity to the induction coil 122. The preform 140 may be placed in a support fixture to firmly hold it at a constant position in relation to the vessel 110 and induction coil 122. The exact shape of the fixture may be based on the shape of the preform 140. For example, the susceptor 124 may support the preform 140 during the rapid-densification process.

During example operation, the power source 530 provides alternating current that passes through the induction coil 122, which creates an electromagnetic field that supplies electromagnetic energy to the susceptor 124. The susceptor 124 converts the electromagnetic energy into heat, which emanates from the susceptor 124 in a generally uniform manner. As described above in regards to FIG. 2, the susceptor 124 transmits heat to the inner surface 242 of the preform 140, increasing a temperature at the inner surface 242 higher than a temperature at the opposing outer surface 244 of the preform 140. The temperature gradient causes the liquid precursor 112 within the preform 140 to begin boiling closer to the center of the preform 140 before the outer surface 244, inducing solid material to form closer to the center of the preform 140 before the outer surface 244. Advantageously, this arrangement enables uniform heating of preform structures which may be conical or non-axisymmetric components such as heatshields.

FIG. 5b shows a variant heating system 520 that supports induction heating of electromagnetically conductive preforms in accordance with certain embodiments. The variant heating system 520 includes an induction coil 522 coupled to a power source 532, which may be similar to the induction coil 122 and power source 530, respectively, as described above in relation to FIG. 5a. However, in contrast to the heating system 120, the heating system 520 operates without a separate susceptor, such as the susceptor 124. Rather, the preform 140 is made of electromagnetically conductive material, enabling the preform 140 itself to act as a susceptor. That is, the preform 140 itself absorbs the electromagnetic energy from the electromagnetic field and converts the electromagnetic energy into heat.

During example operation, the power source 532 provides alternating current that passes through the induction coil 522, which creates an electromagnetic field that supplies electromagnetic energy directly to the preform 140. The preform 140 converts the electromagnetic energy into heat. This arrangement creates a temperature gradient across the preform 140, with a temperature of the internal region of the preform 140 being generally higher than external regions of the preform 140, which experience heat loss to the surrounding liquid precursor 112. That is, the surrounding liquid precursor 112 acts as a heat sink that cools the outer surfaces of the preform 140. This temperature gradient causes liquid precursor 112 within the preform 140 to begin boiling before the liquid precursor 112 in the external regions, inducing solid material to form within the internal region before the external regions.

It should be appreciated that the heating system 520 causes densification to progress differently than densification using the heating system 120. As shown in FIG. 2, the heating system 120 creates hotter regions near the inner surface 242 of the preform 140 in contact with the susceptor 124, which induces densification to begin near the inner surface 242 and progress toward the opposing outer surface 244 of the preform 140. In contrast, the heating system 520 creates hotter regions within the preform 140 itself, which induces densification to progress “inside-out” (that is, beginning within the preform 140 and progressing outwardly in all directions). Advantageously, such heating support densification of certain components with complex geometries.

FIG. 5c shows another variant heating system 522 that support resistive heating of conductive preforms in accordance with certain embodiments. As shown, a power source 534 is coupled to directly to the preform 140. During operation, the power source 534 provides current or voltage (e.g., direct or alternating) that heats the preform directly based on resistive power dissipation within the preform 140. Similar to the heating system 520, the heating system 522 generates heat within the preform 140, which may result in a similar progression of densification from the “inside-out.” Advantageously, the resistive heating provided by the heating system 522 may be performed without an induction coil.

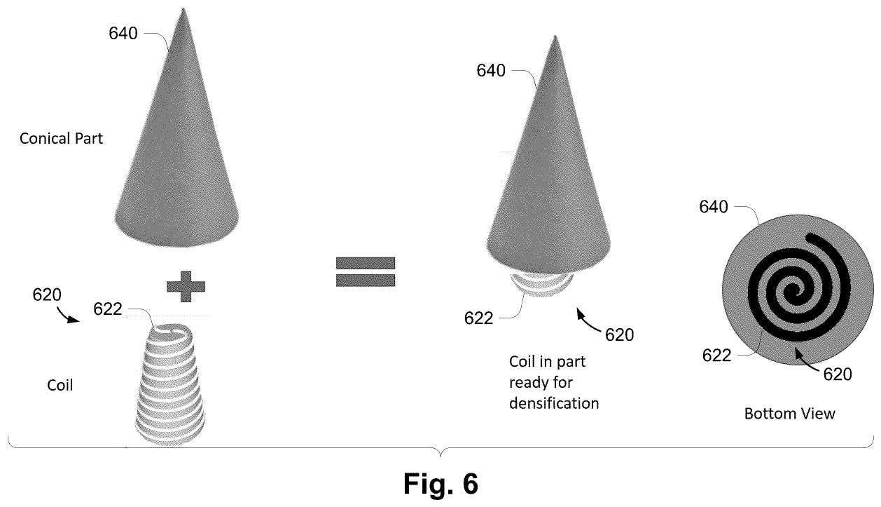

FIG. 6 shows different views of an alternatively shaped heating system 620 for use in the rapid-densification system 100 in accordance with certain embodiments. FIG. 6 illustrates certain changes that may be made to the heating system 120 (FIGS. 1, 2, and 5a) to accommodate components of different sizes and/or shapes. It should be appreciated that some or all of these changes may be applicable to the other heating systems 520, 522 (FIGS. 5b and 5c) previously described.

As shown, the heating system 620 includes an induction coil 622 having a different coil shape than the induction coil 122 of the heating system 120. A preform 640 (e.g., a heatshield) is placed over the induction coil 622, with both being located in the vessel 110 (FIG. 1) so as to be covered by the liquid precursor 112. In this example, the induction coil 622 is shaped differently than the induction coil 122 of the heating system 120, enabling the induction coil 622 to support alternative component positioning. More generally, for induction heating applications, coil shape and component positioning may be selected to conform to the shape of the preform being processed. For example, the diameter of the induction coil 622 may be smaller where the diameter of the preform is smaller. Alternatively, a turn density of the induction coil 622 can be increased in areas where the object to be heated is further from the coil.

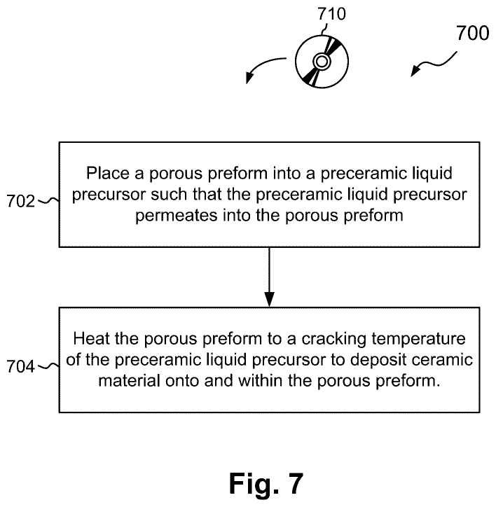

FIG. 7 shows an example procedure 700 that may be carried out using the rapid-densification system 100 (FIG. 1) in accordance with certain embodiments. The various acts of procedure 700 may be ordered in any suitable way. Accordingly, embodiments may be constructed in which acts are performed in orders different from that illustrated, which may include performing some acts simultaneously.

At 702, the porous preform 140 is placed into the liquid precursor 112 such that the preceramic liquid precursor permeates into the porous preform. In some arrangements, the liquid precursor 112 is supplied in sufficient amounts to cover (e.g., submerge) the porous preform 140 to deprive the preform 140 of oxygen. Further, the liquid precursor 112 may be selected based on the requirements of the particular application. For example, a preceramic liquid or hydrocarbon liquid may be provided to deposit ceramic material or carbon material, respectively.

At 704, the porous preform 140 is heated to a cracking temperature of the liquid precursor 112 to deposit solid material onto the preform. Deposition of the solid material begins within an internal region of the porous preform and advancing outwardly toward an external region of the porous preform. As described above, the solid material deposited depends on the selected liquid precursor 112. In some arrangements, electrical current is applied to the heating system 120 (and/or heating systems 520, 522) over a multi-hour period of densification in which the liquid precursor 112 is continually boiled and the precursor gases continually produced. The electrical current should be sufficient to maintain the preform 140 at a densification temperature at or above the cracking temperature of the liquid precursor 112, thereby causing the precursor gases to be diffused into the preform 140 and dissociated gas species to be deposited. As described above, densification thus begins within the preform and advances outwardly along a densification front until completion.

Once densification is complete, the densified component can be machined or processed in other ways as necessary to produce a completely finished component for an intended application. This further processing could include removing the preform 140 from the deposited material to create pores or voids in the final component. Additionally or alternatively, further processing may include application of a protective surface layer such as an inorganic compound, which can reduce/prevent oxidation and extend operating lifetime such as in a long-glide application.

Having described certain embodiments, numerous alternative embodiments or variations can be made. For example, although the present disclosure describes an embodiment based on a conical component such as a nosecone heatshield, it will be understood that the disclosed technique can be applied to various alternative thermal protection system components. These include, inter alia, nosetips, as well as acreage, leading edge, or control surfaces for vehicles. Component shapes may, of course, be other than conical; they could be elliptical (axis-symmetric), or even asymmetric, depending on the vehicle or component design. As another example, some arrangements may employ one or more additional heating systems placed to provide overall conformance to the shape of the preform 140, and during operation all heating systems are energized (e.g., fed with electrical current) in a manner that provides a desired heating pattern for the rapid densification process.

Further, although features have been shown and described with reference to particular embodiments hereof, such features may be included and hereby are included in any of the disclosed embodiments and their variants. Thus, it is understood that features disclosed in connection with any embodiment are included in any other embodiment.

Further still, the improvement or portions thereof may be embodied as a computer program product including one or more non-transient, computer-readable storage media, such as a magnetic disk, magnetic tape, compact disk, DVD, optical disk, flash drive, solid state drive, SD (Secure Digital) chip or device, Application Specific Integrated Circuit (ASIC), Field Programmable Gate Array (FPGA), and/or the like (shown by way of example as medium 710 in FIG. 7). Any number of computer-readable media may be used. The media may be encoded with instructions which, when executed on one or more computers or other processors, perform the process or processes described herein. Such media may be considered articles of manufacture or machines, and may be transportable from one machine to another.

As used throughout this document, the words “comprising,” “including,” “containing,” and “having” are intended to set forth certain items, steps, elements, or aspects of something in an open-ended fashion. Also, as used herein and unless a specific statement is made to the contrary, the word “set” means one or more of something. This is the case regardless of whether the phrase “set of” is followed by a singular or plural object and regardless of whether it is conjugated with a singular or plural verb. Also, a “set of” elements can describe fewer than all elements present. Thus, there may be additional elements of the same kind that are not part of the set. Further, ordinal expressions, such as “first,” “second,” “third,” and so on, may be used as adjectives herein for identification purposes. Unless specifically indicated, these ordinal expressions are not intended to imply any ordering or sequence. Thus, for example, a “second” event may take place before or after a “first event,” or even if no first event ever occurs. In addition, an identification herein of a particular element, feature, or act as being a “first” such element, feature, or act should not be construed as requiring that there must also be a “second” or other such element, feature or act. Rather, the “first” item may be the only one. Also, and unless specifically stated to the contrary, “based on” is intended to be nonexclusive. Thus, “based on” should be interpreted as meaning “based at least in part on” unless specifically indicated otherwise. Although certain embodiments are disclosed herein, it is understood that these are provided by way of example only and should not be construed as limiting.

Those skilled in the art will therefore understand that various changes in form and detail may be made to the embodiments disclosed herein without departing from the scope of the following claims.

What is claimed is:

1. A method of manufacturing a ceramic component, the method comprising:
placing a porous preform into a preceramic liquid precursor such that the preceramic liquid precursor permeates into the porous preform; and
heating the porous preform to a cracking temperature of the preceramic liquid precursor to deposit ceramic material onto and within the porous preform.

2. The method of claim 1, further comprising:
forming the preceramic liquid precursor at least in part by mixing multiple preceramic materials, such that the ceramic material deposited onto the porous preform is a high-entropy ceramic (HEC) material.

3. The method of claim 2, wherein the preceramic materials include at least two of the following: (i) silicon carbide, (ii) titanium carbide, (iii) hafnium carbide, (iv) zirconium carbide, (v) tantalum carbide, (vi) titanium butoxide, and (vii) zirconium butoxide.

4. The method of claim 2, wherein heating the porous preform causes a portion of the preceramic liquid precursor within the porous preform to boil and create a dissociated gas species that forms the ceramic material within the porous preform.

5. The method of claim 2, wherein heating the porous preform increases an internal temperature within a thickness of the porous preform above a surface temperature at a surface of the porous preform and induces the ceramic material to form internally within porous preform before forming at the surface.

6. The method of claim 5,
wherein the porous preform is electrically conductive, and
wherein heating the porous preform includes inductively heating the porous preform.

7. The method of claim 5,
wherein the porous preform has an electrical resistance, and
wherein heating the porous preform includes passing electric current through the porous preform to resistively heat the porous preform.

8. The method of claim 2,
wherein the porous preform includes a first surface and a second surface opposite the first surface; and
wherein heating the porous preform increases a temperature of the first surface above a temperature of the second surface and induces a portion of the preceramic liquid precursor within the porous preform to form the ceramic material starting at the first surface and advancing toward the second surface.

9. The method of claim 8, wherein heating the porous preform includes inductively heating a susceptor adjacent to the porous preform, such that the susceptor transfers heat to the porous preform.

10. The method of claim 2,
wherein the porous preform includes carbon-based strands, and
wherein placing the porous preform into the preceramic liquid precursor enables the preceramic liquid precursor to permeate into the porous preform through spaces between the carbon-based strands.

11. The method of claim 10, wherein the carbon-based strands include submicron carbon nanotubes.

12. The method of claim 11, further comprising:
removing the carbon-based strands from the ceramic material to create submicron pores in the ceramic material, the submicron pores inhibiting crack propagation within the ceramic component.

13. The method of claim 2, further comprising:
removing at least a portion of the porous preform from the ceramic material to create voids in the ceramic material, the voids inhibiting crack propagation within the ceramic component.

14. The method of claim 13, wherein removing the porous preform from the ceramic material includes:
exposing the porous preform to an oxygen-containing environment; and
while the porous preform is exposed to the oxygen-containing environment, heating the porous preform above an oxidation temperature of the porous preform to form a gaseous oxide from the portion of the porous preform.

15. The method of claim 14,
wherein the porous preform includes carbon, and
wherein heating the porous preform above the oxidation temperature of the porous preform while the porous preform is exposed to the oxygen-containing environment creates carbon dioxide from the porous preform.

16. The method of claim 13, wherein removing the porous perform creates internal surfaces in the ceramic component, the internal surfaces promoting transpirational cooling of the ceramic component.

17. A ceramic component, comprising:
a high-entropy ceramic (HEC) material having submicron pores, the submicron pores inhibiting crack propagation within the ceramic component.

18. The ceramic component of claim 17, wherein the ceramic component is a nosecone heatshield.
